(19) United States
(12) Patent Application Publication
(10) Pub. No.: US 2026/0239955 A1
(43) Pub. Date: Aug. 13, 2026

(54) SEMICONDUCTOR DEVICE AND METHOD OF MANUFACTURING SEMICONDUCTOR DEVICE

(71) Applicant: SK hynix Inc., Gyeonggi-do (KR)

(72) Inventor: Dae Sung EOM, Gyeonggi-do (KR)

(21) Appl. No.: 19/212,701

(22) Filed: May 20, 2025

(30) Foreign Application Priority Data
Feb. 10, 2025 (KR) 10-2025-0016742

(51) Int. Cl. H01L 23/528; H01L 21/768; H01L 23/00; H01L 25/065; H01L 25/18; H10B 41/27; H10B 41/41; H10B 43/27; H10B 43/40; H10B 80/00

(52) U.S. Cl. CPC H10W 20/435; H10B 41/27; H10B 41/41; H10B 43/27; H10B 43/40; H10B 80/00; H10W 20/056; H10W 20/089; H10W 90/00; H10W 90/792

(57) ABSTRACT

A semiconductor device includes: a first dielectric layer; a second dielectric layer located on the first dielectric layer; and a first wiring line including first conductive patterns located in the first dielectric layer, each of the first conductive patterns having an inverted trapezoidal shape, and second conductive patterns located in the second dielectric layer, each of the second conductive patterns having a trapezoidal shape, wherein the first conductive patterns and the second conductive patterns are alternately connected to each other.

### CROSS-REFERENCE TO RELATED APPLICATION

This application claims priority under 35 U.S.C. § 119 to Korean Patent Application No. 10-2025-0016742 filed on Feb. 10, 2025, which is incorporated herein by reference in its entirety.

### BACKGROUND

### 1. Technical Field

Embodiments of the present disclosure relate to an electronic device, and more particularly, to a semiconductor device and a method of manufacturing the semiconductor device.

### 2. Related Art

Semiconductor devices are known to include interconnections, such as a wiring line and a contact plug for electrical connection between elements. Recently, in order to improve the operational speed and reliability of semiconductor devices, there have been increasing efforts to develop and improve materials, structures, manufacturing methods, and the like, of the interconnections.

### SUMMARY

In an embodiment, a semiconductor device may include: a first dielectric layer; a second dielectric layer located over the first dielectric layer; and a first wiring line including first conductive patterns located in the first dielectric layer, each of the first conductive patterns having an inverted trapezoidal shape, and second conductive patterns located in the second dielectric layer, each of the second conductive patterns having a trapezoidal shape, wherein the first conductive patterns and the second conductive patterns are alternately connected to each other.

In an embodiment, a semiconductor device may include: a first dielectric layer; a second dielectric layer located over the first dielectric layer; a first wiring line including first conductive patterns located in the first dielectric layer and second conductive patterns located in the second dielectric layer, the first conductive patterns and the second conductive patterns being alternately connected to each other; and a second wiring line including third conductive patterns located in the first dielectric layer and fourth conductive patterns located in the second dielectric layer, the third conductive patterns and the fourth conductive patterns being alternately connected to each other, wherein the first wiring line and the second wiring line may extend in parallel along a first direction.

In an embodiment, a method of manufacturing a semiconductor device may include: forming first openings in a first dielectric layer, the first openings being arranged along a first direction; forming a second opening in the first dielectric layer, the second opening connecting the first openings to each other; forming a conductive layer in the first openings and the second opening, the conductive layer including first conductive patterns located in the first openings and a bulk conductive pattern located in the second opening; and forming second conductive patterns by etching the bulk conductive pattern, the second conductive patterns connecting the first conductive patterns to each other.

In an embodiment, a method of manufacturing a semiconductor device may include: forming a first opening in an interlayer insulating layer; forming a dielectric layer in the first opening; forming second openings and third openings in the dielectric layer, the second openings being arranged in a first direction and the third openings being arranged in the first direction and being staggered with the second openings; forming a fourth opening by etching the dielectric layer, the fourth opening connecting the second openings and the third openings to each other; forming a conductive layer including first conductive patterns, third conductive patterns and a bulk conductive pattern, wherein the first conductive patterns are located in the second openings, the third conductive patterns are located in the third openings, and the bulk conductive pattern is connected to the first conductive patterns and the third conductive patterns; and forming second conductive patterns and fourth conductive patterns by etching the bulk conductive pattern, the second conductive patterns connecting the first conductive patterns to each other, and the fourth conductive patterns connecting the third conductive patterns to each other.

### BRIEF DESCRIPTION OF THE DRAWINGS

FIGS. 1A to 1C are diagrams illustrating a top view and cross sectional views of the structure of a semiconductor device in accordance with an embodiment of the present disclosure.

FIG. 2 is a diagram illustrating the structure of a semiconductor device in accordance with an embodiment of the present disclosure.

FIG. 3 is a diagram illustrating the structure of a semiconductor device in accordance with an embodiment of the present disclosure.

FIG. 4 is a block diagram illustrating the structure of a semiconductor device in accordance with an embodiment of the present disclosure.

FIGS. 5A, 6A, 7A, 8A, and 9A and FIGS. 5B, 6B, 7B, 8B, and 9B are diagrams for describing a method of manufacturing a semiconductor device in accordance with an embodiment of the present disclosure.

FIG. 10 is a configuration diagram of a semiconductor device in accordance with an embodiment of the present disclosure.

FIG. 11 is a configuration diagram of a semiconductor device in accordance with an embodiment of the present disclosure.

### DETAILED DESCRIPTION

Various embodiments are directed to a semiconductor device having a stable structure and improved characteristics and a method of manufacturing the semiconductor device.

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the spirit and scope of the present disclosure as defined in the appended claims.

The embodiments of the present disclosure are described herein with reference to cross-section and/or plan illustrations of the embodiments. However, the embodiments of the present disclosure should not be construed as limiting the inventive concept. Although a few embodiments of the present disclosure will be shown and described, it will be appreciated by those of ordinary skill in the art that changes may be made in these embodiments without departing from the principles and scope of the present disclosure.

It will be understood that, although the terms “first”, “second”, “third”, and so on may be used herein to describe various elements, these elements are not limited by these terms. These terms are used to distinguish one element from another element. Thus, a first element described below could also be termed as a second or third element without departing from the principles and scope of the present disclosure.

It will be further understood that when an element is referred to as being “connected to”, or “coupled to” another element, it may be directly on, connected to, or coupled to the other element, or one or more intervening elements may be present. Furthermore, the connection/coupling may not be limited to a physical connection but may also include a non-physical connection, e.g., a wireless connection.

In addition, it will also be understood that when an element is referred to as being “between” two elements, it may be the only element between the two elements, or one or more intervening elements may also be present.

When a first element is referred to as being “over” a second element, it not only refers to a case where the first element is formed directly on the second element but also a case where a third element exists between the first element and the second element. When a first element is referred to as being “on” a second element, it refers to a case where the first element is formed directly or indirectly on the second element or the substrate.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

It should be understood that the drawings are simplified schematic illustrations of the described devices and may not include well known details to avoid obscuring the features of the embodiments.

It should also be noted that features present in one embodiment may be used with one or more features of another embodiment without departing from the scope of the present disclosure.

It is further noted, that in the various drawings, like reference numbers designate like elements.

The embodiments of the present disclosure provide a semiconductor device having a stable structure and improved reliability.

Hereafter, embodiments in accordance with the technical spirit of the present disclosure will be described with reference to the accompanying drawings.

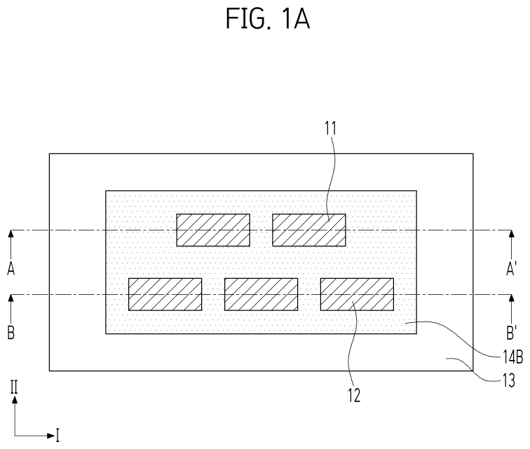

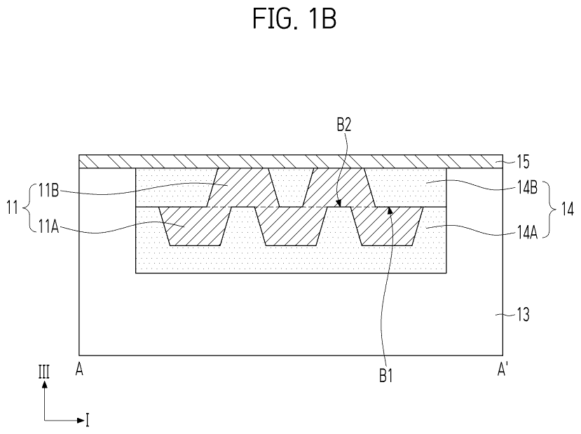

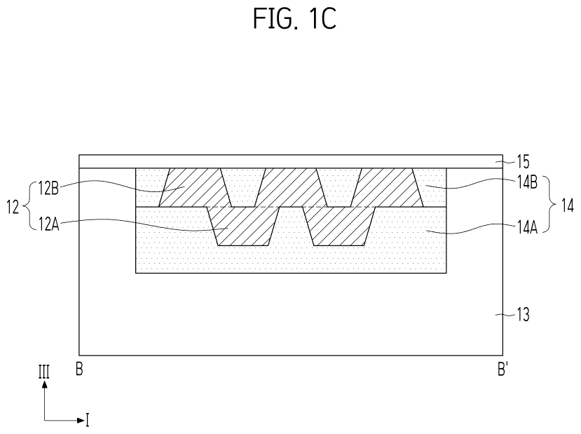

FIGS. 1A to 1C are diagrams illustrating the structure of a semiconductor device in accordance with an embodiment. FIG. 1A is a top perspective view while FIG. 1B is a cross-sectional view of the semiconductor device taken along line A-A′ illustrated in FIG. 1A, and FIG. 1C is a cross-sectional view of the semiconductor device taken along line B-B′ illustrated in FIG. 1A.

Referring to FIGS. 1A to 1C, the semiconductor device may include a first wiring line 11 and a dielectric layer 14. The semiconductor device may further include a second wiring line 12, an interlayer insulating layer 13, and a capping layer 15.

The interlayer insulating layer 13 may include an insulating material such as oxide. In an example, the interlayer insulating layer 13 may include tetraethyl orthosilicate (TEOS). The dielectric layer 14 may be located in the interlayer insulating layer 13. The dielectric layer 14 may include a first dielectric layer 14A and a second dielectric layer 14B. The first dielectric layer 14A and the second dielectric layer 14B may be stacked in a third direction III, and the second dielectric layer 14B may be located above the first dielectric layer 14A. The third direction III may perpendicularly intersect a first direction I and a second direction II. The dielectric layer 14 may include a low-k material having a lower dielectric constant than the interlayer insulating layer 13. In an example, the dielectric layer 14 may include carbon doped silicon oxide (carbon doped SiO₂) or fluorine doped silicon oxide (fluorine doped SiO₂).

The first wiring line 11 may be located in the dielectric layer 14, and may extend in the first direction I. The first wiring line 11 may include a first conductive pattern 11A located in the first dielectric layer 14A and a second conductive pattern 11B located in the second dielectric layer 14B. The first wiring line 11 may include first conductive patterns 11A (for example, bottom three inverted trapezoids in FIG. 1B) and second conductive patterns 11B (for example, top two trapezoids in FIG. 1B) that are alternately connected to each other. The first conductive pattern 11A may have a reverse trapezoidal shape (for example, an upside-down or inverted trapezoid), and the second conductive pattern 11B may have a trapezoidal shape. A long side B1 of parallel opposite sides of the first conductive pattern 11A and a long side B2 of parallel opposite sides of the second conductive pattern 11B may be in contact with each other (for example, the base (or bottom) of (the trapezoidal shape of) second conductive pattern B2 and the top of (the inverted trapezoidal shape of) the first conductive pattern B1 may be in contact with each other). The first conductive patterns 11A and the second conductive patterns 11B included in the first wiring line 11 may be connected to each other as one layer. In an example, an interface might not exist between the first conductive patterns 11A and the second conductive patterns 11B. The first conductive patterns 11A and the second conductive patterns 11B may be different parts of a same layer. The first wiring line 11 may include metal such as tungsten (W), copper (Cu), or aluminum (Al).

The second wiring line 12 may be located in the dielectric layer 14, and may extend in the first direction I. The second wiring line 12 may include a third conductive pattern 12A located in the first dielectric layer 14A and a fourth conductive pattern 12B located in the second dielectric layer 14B. The second wiring line 12 may include third conductive patterns 12A and fourth conductive patterns 12B that are alternately connected to each other. The third conductive pattern 12A may have a reverse trapezoidal shape, and the fourth conductive pattern 12B may have a trapezoidal shape. A long side B1 of parallel opposite sides of the third conductive pattern 12A and a long side B2 of parallel opposite sides of the fourth conductive pattern 12B may be in contact with each other. The third conductive patterns 12A and the fourth conductive patterns 12B included in the second wiring line 12 may be connected to each other as one layer. In an example, an interface might not exist between the third conductive patterns 12A and the fourth conductive patterns 12B. The second wiring line 12 may include metal such as tungsten (W), copper (Cu), or aluminum (Al).

The first wiring line 11 and the second wiring line 12 may extend in parallel along the first direction, and may be adjacent to each other (for example, beside or next to each other without any intervening structure in the dielectric layer 14) in the second direction II intersecting the first direction I. The first conductive pattern 11A and the fourth conductive pattern 12B may be disposed to correspond to each other, and the first conductive pattern 11A and the fourth conductive pattern 12B located at different levels may be adjacent to each other in the second direction II. The second conductive pattern 11B and the third conductive pattern 12A may be disposed to correspond to each other, and the second conductive pattern 11B and the third conductive pattern 12A located at different levels may be adjacent to each other in the second direction II. The first conductive pattern 11A and the third conductive pattern 12A located at the same level may be staggered, and, in some instances, may not be adjacent to each other in the second direction II. The second conductive pattern 11B and the fourth conductive pattern 12B located at the same level may be staggered, and might not be adjacent to each other in the second direction II.

The capping layer 15 may be located on the interlayer insulating layer 13 and the dielectric layer 14. The capping layer 15 may be used to protect the first wiring line 11 and the second wiring line 12 in a manufacturing process, and may reduce oxidation of the first wiring line 11 and the second wiring line 12. The capping layer 15 may include a material having a higher dielectric constant than the interlayer insulating layer 13 and the dielectric layer 14. In an example, the capping layer 15 may include silicon nitride.

According to the structure described above, particularly with reference to FIG. 1, by staggering the conductive patterns 11A, 11B, 12A, and 12B, included in the first wiring line 11 and the second wiring line 12 extending in parallel along the first direction I in a vertical direction, the embodiments provide a capability to reduce an area where the first wiring line 11 and the second wiring line 12 face each other. In addition, the first wiring line 11 and the second wiring line 12 may be located in the dielectric layer 14 including the low-k material. Accordingly, capacitance between the first wiring line 11 and the second wiring line 12 may be reduced.

Meanwhile, defects may exist at interfaces between the first and second wiring lines 11 and 12 and the capping layer 15. The interfaces may become unstable due to defects caused in a manufacturing process, and bridges may be caused at the interfaces. Such a phenomenon may be deepened as program, read, and/or erase operations are repeated or as a voltage difference between the first and second wiring lines 11 and 12 increases. Accordingly, by forming the first and second wiring lines 11 and 12 staggered in the vertical direction, the embodiments reduce the capacitance between the first wiring line 11 and the second wiring line 12 and reduce stress between the first wiring line 11 and the second wiring line 12. Through this, the interfaces may be stabilized, and the occurrence of the bridges may be reduced. In addition, the first and second wiring lines 11 and 12 are in discontinuous contact with the capping layer 15, and thus, a path through which the bridges occur may be reduced.

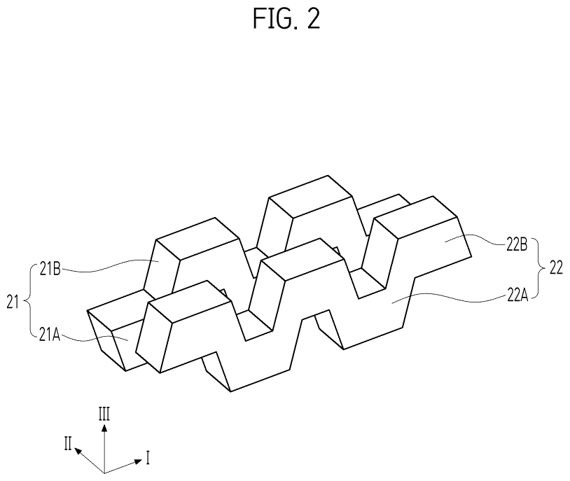

FIG. 2 is a diagram illustrating the structure of a semiconductor device in accordance with an embodiment. Hereinafter, the content overlapping with the previously described content may be omitted.

Referring to FIG. 2, the semiconductor device may include a first wiring line 21 and a second wiring line 22. The first wiring line 21 may include first conductive patterns 21A and second conductive patterns 21B, and the first conductive patterns 21A and the second conductive patterns 21B may be staggered in the vertical direction. The second wiring line 22 may include third conductive patterns 22A and fourth conductive patterns 22B, and the third conductive patterns 22A and the fourth conductive patterns 22B may be staggered in the vertical direction.

The first wiring line 21 and the second wiring line 22 may extend in parallel along the first direction I, and may be adjacent to each other in the second direction II. The first conductive pattern 21A and the fourth conductive pattern 22B adjacent to each other in the second direction II may be staggered in the vertical direction. The second conductive pattern 21B and the third conductive pattern 22A adjacent to each other in the second direction II may be staggered in the vertical direction.

The first wiring line 21 may be a high-voltage node for transmitting a high-voltage signal such as a program voltage or an erase voltage. The second wiring line 22 may be a low-voltage node for transmitting a low-voltage signal such as a ground voltage or a control signal. When the high-voltage signal and the low-voltage signal flow respectively through the first wiring line 21 and the second wiring line 22 arranged in parallel, a defect such as a bridge or a breakdown may be caused by a great voltage difference (for example, in excess of a particular maximum voltage difference) between the first wiring line 21 and the second wiring line 22. Accordingly, by forming the first wiring line 21 and the second wiring line 22 extending in parallel along the first direction I in a staggered arrangement in the vertical direction, the embodiments reduce an area where the first wiring line 21 and the second wiring line 22 face each other and reduce defects such as the bridge (or bridging) and the breakdown.

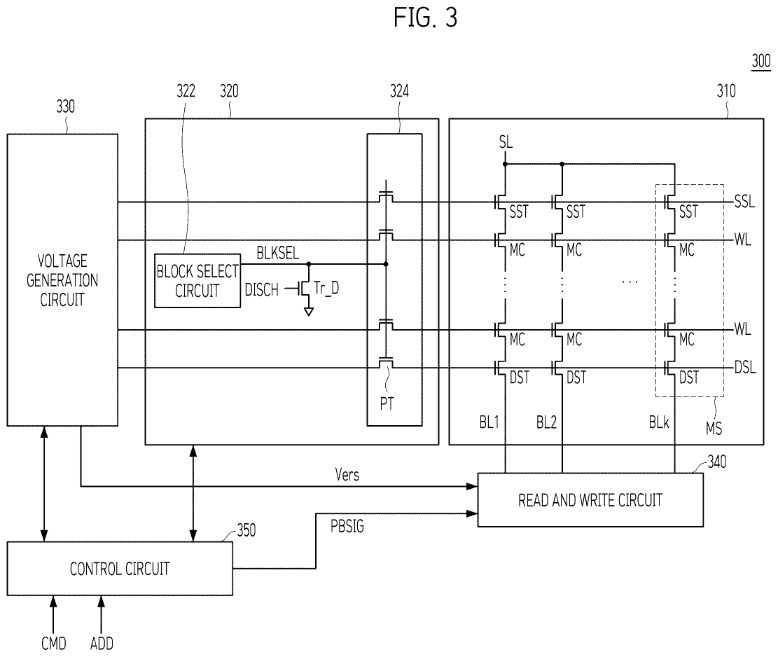

FIG. 3 is a block diagram illustrating the configuration of a semiconductor device in accordance with an embodiment. Hereinafter, content overlapping with the previously described content may be omitted.

Referring to FIG. 3, the semiconductor device 300 may include a memory cell array 310, an address decoder 320, a voltage generation circuit 330, a read and write circuit 340, and a control circuit 350.

The memory cell array 310 may include a plurality of memory blocks, each of which may include pages. The memory block may be a unit of an erase operation, and the page may be a unit of a read operation. The memory cell array 310 may be connected to the address decoder 320 through row lines such as a source select line SSL, a word line WL, and a drain select line DSL. The memory cell array 310 may be connected to the read and write circuit 340 through column lines such as bit lines BL0 to BLk. The read and write circuit 340 may include a plurality of page buffers connected to the bit lines BL0 to BLk. Here, k may be an integer of 2 or more.

Each memory block may include memory strings MS. The memory strings MS may be connected between bit lines BL1 to BLk and a source line SL. Each memory string MS may include at least one drain select transistor DST, a plurality of memory cells MC, and at least one source select transistor SST. A connection between the memory string MS and the source line SL may be controlled by the source select line SSL. A connection between the memory string MS and the bit lines BL1 to BLk may be controlled by the drain select line DSL.

The control circuit 350 may receive a command CMD and an address ADD from a controller (not shown in FIG. 3). The control circuit 350 may generate control signals to perform internal operations such as a program operation, a read operation, and an erase operation according to the received command CMD. The control circuit 350 may output the control signals to the voltage generation circuit 330, the address decoder 320, and the read and write circuit 340. In an example, the control circuit 350 may output a page buffer control signal PBSIG to the read and write circuit 340, and the page buffers may operate in response to the page buffer control signal PBSIG.

The voltage generation circuit 330 may generate internal voltages of various voltage levels for performing the internal operations, and may provide the generated internal voltages to the address decoder 320 and the read and write circuit 340. The internal voltage may be an operation voltage for performing the program operation, the read operation, the erase operation, or the like. The voltage generation circuit 330 may include a high-voltage generation pump for generating a high-voltage signal such as a program voltage or an erase voltage.

The address decoder 320 may include a block select circuit 322 and a pass circuit 324. The pass circuit 324 may include pass transistors PT for controlling connections between global lines and local lines. The pass transistors PT may be high-voltage transistors. The block select circuit 322 may generate a block select signal BLKSEL in response to an address, and may transmit the generated block select signal BLKSEL to the pass circuit 324. A discharge transistor Tr_D may discharge a line for transmitting the block select signal BLKSEL in response to a discharge signal DISCH. The pass circuit 324 may operate in response to the block select signal BLKSEL.

During the program operation, a program voltage and/or a pass voltage generated by the voltage generation circuit 330 may be transmitted to the global word line and transmitted to the word line WL through the pass circuit 324. During the read operation, a read voltage and/or a pass voltage generated by the voltage generation circuit 330 may be transmitted to the global word line and transmitted to the word line WL through the pass circuit 324. During the erase operation, an erase voltage generated by the voltage generation circuit 330 may be transmitted to the bit lines BL0 to BLk and/or the source line SL.

According to the configuration described above, the semiconductor device may include wiring lines for transmitting an operation voltage, a ground voltage, a control signal, and the like. The wiring lines may include the first wiring line and the second wiring line described above with reference to FIGS. 1A to 1C and FIG. 2. The first wiring line and the second wiring line may extend in parallel along one direction, a high-voltage signal may be transmitted through the first wiring line, and a low-voltage signal may be transmitted through the second wiring line.

According to an example embodiment, the first wiring line and the second wiring line may be connected to the pass transistors PT of the address decoder 320. The global word lines are arranged in parallel to extend along one direction, and are connected to the pass transistors PT, which are the high-voltage transistors. During the program operation, the program voltage is transmitted through a selected global word line, and the pass voltage is transmitted through an unselected global word line. The pass voltage is used to boost a channel of an unselected memory cell, and may have a lower voltage level than the program voltage. Accordingly, by applying the first wiring line and the second wiring line to the global word lines, a bridge caused between the global word lines may be reduced.

According to another example embodiment, the high-voltage signal such as the program voltage or the erase voltage Vers may be transmitted through the first wiring line, and the ground voltage Vss may be transmitted through the second wiring line. The first wiring line may be connected to the high-voltage generation pump of the voltage generation circuit 330. As the first wiring line and the second wiring line extend in parallel, the second wiring line may provide an electrical shielding effect to the first wiring line. The high-voltage signal transmitted through the first wiring line may be stably maintained without external interference. In addition, even though a voltage level difference between the first wiring line and the second wiring line is great, the bridge may be reduced through a form in which the first wiring line and the second wiring line are staggered in the vertical direction.

According to an example embodiment, the first wiring line and the second wiring line may be connected to the read and write circuit 340, and the first wiring line may be connected to a high-voltage transistor of the page buffer included in the read and write circuit 340. The erase voltage Vers generated by the voltage generation circuit 330 may be transmitted to the read and write circuit 340 through the first wiring line. The page buffer control signal PBSIG generated by the control circuit 350 may be transmitted to the read and write circuit 340 through the second wiring line. The page buffer control signal PBSIG is a type of control signal, and may have a low-voltage level. Even though the voltage level difference between the first wiring line and the second wiring line is great, the bridge may be reduced through the form in which the first wiring line and the second wiring line are staggered in the vertical direction.

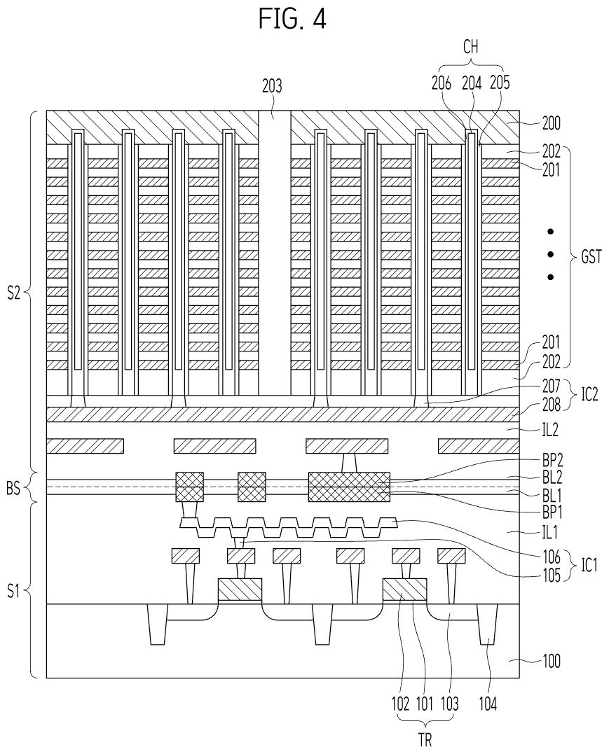

FIG. 4 is a diagram illustrating the structure of a semiconductor device in accordance with an embodiment. Hereinafter, the content overlapping with the previously described content may be omitted.

Referring to FIG. 4, the semiconductor device may include a first semiconductor structure S1, a second semiconductor structure S2, and a bonding structure BS located between the first semiconductor structure S1 and the second semiconductor structure S2. The first semiconductor structure S1 and the second semiconductor structure S2 may be formed by separate processes, and may be electrically connected to each other by the bonding structure BS. In an example, the first semiconductor structure S1 may include a peripheral circuit, and the second semiconductor structure S2 may include a memory cell array.

The first semiconductor structure S1 may include a substrate 100, a transistor TR, a first interconnection structure IC1, and a first interlayer insulating layer IL1. An active region may be defined by an element isolation layer 104 in the substrate 100, and the transistor TR may be located in the active region. The transistor TR may include a gate insulating layer 101, a gate electrode 102, and a junction 103. The transistor TR may belong to the peripheral circuit. In an example, the peripheral circuit may include a read and write circuit, a page buffer, an address decoder, a voltage generation circuit, a control circuit, an input/output circuit, and the like, as shown in FIG. 3.

The first interconnection structure IC1 may be located in the first interlayer insulating layer IL1, and may include a via 105, a wiring line 106, and the like. The first interconnection structure IC1 may be electrically connected to the peripheral circuit, and may be electrically connected to the transistor TR. The wiring line 106 may have a structure according to the embodiment described above with reference to FIGS. 1A to 1C and FIG. 2. For reference, the dielectric layer including the low-k material may be located in the first interlayer insulating layer IL1, and the wiring line 106 may be located in the dielectric layer.

The second semiconductor structure S2 may include a source structure 200, a gate structure GST, a slit structure 203, a second interconnection structure IC2, and a second interlayer insulating layer IL2. The source structure 200 may be located above or below the gate structure GST. The source structure 200 may include a conductive material such as polysilicon or metal.

The gate structure GST may include conductive layers 201 and insulating layers 202 that are alternately stacked. The conductive layers 201 may be gate lines such as a source select line, a drain select line, and word lines. A channel structure CH may extend through the gate structure GST, and may be connected to the source structure 200. The channel structure CH may include a channel layer 204, a memory layer 205, and an insulating core 206. The slit structure 203 may extend through the gate structure GST. The slit structure 203 may include an insulating material, a conductive material, a semiconductor material, or the like.

The second interconnection structure IC2 may be located in the second interlayer insulating layer IL2 and may include a via 207, a wiring line 208, and the like. The second interconnection structure IC2 may be electrically connected to the channel structure CH, the gate structure GST, and the like. The wiring line 208 may have a structure according to the embodiment described above with reference to FIGS. 1A to 1C and FIG. 2. For reference, the dielectric layer including the low-k material may be located in the second interlayer insulating layer IL2, and the wiring line 208 may be located in the dielectric layer.

The bonding structure BS may include a first bonding layer BL1, a second bonding layer BL2, a first bonding pad BP1, and a second bonding pad BP2. The first bonding layer BL1 and the second bonding layer BL2 may be in contact with each other, and the first bonding pad BP1 and the second bonding pad BP2 may be in contact with each other. The first bonding layer BL1 and the second bonding layer BL2 may each include silicon carbon nitride (SiCN), tetraethyl orthosilicate (TEOS), or the like. The first bonding pad BP1 may be electrically connected to the first interconnection structure IC1, and the second bonding pad BP2 may be electrically connected to the second interconnection structure IC2. The memory cell array and the peripheral circuit may be electrically connected to each other through the first bonding pad BP1 and the second bonding pad BP2.

According to the structure described above, the first semiconductor structure S1 including the peripheral circuit and the second semiconductor structure S2 including the memory cell array may be electrically connected to each other through the bonding structure BS. At least one of the first interconnection structure IC1 and the second interconnection structure IC2 may include first and second wiring lines extending in parallel along one direction and staggered in the vertical direction.

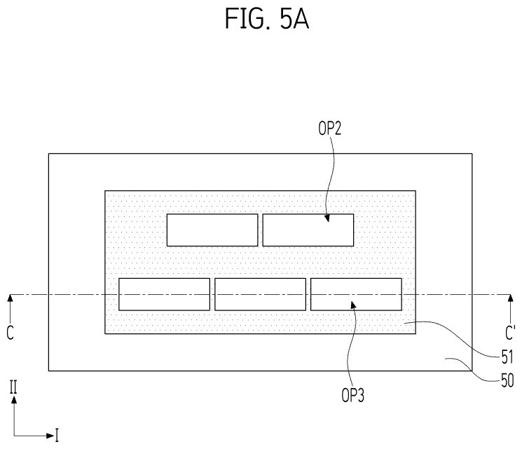

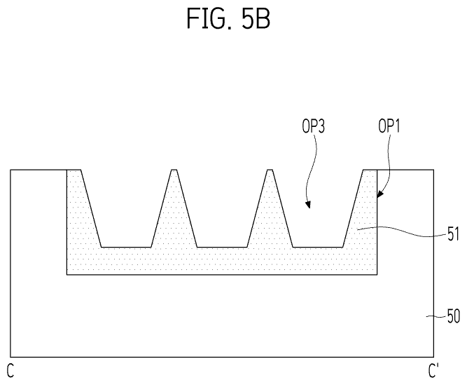

FIGS. 5A, 6A, 7A, 8A, and 9A and respective cross-sectional views FIGS. 5B, 6B, 7B, 8B, and 9B are diagrams for describing a method of manufacturing a semiconductor device in accordance with an embodiment. Hereinafter, the content overlapping with the previously described content may be omitted.

Referring to FIG. 5A and cross-sectional view FIG. 5B, taken along the line C-C′ of FIG. 5A, a first opening OP1 may be formed in an interlayer insulating layer 50, and a first dielectric layer 51 may be formed in the first opening OP1. The first dielectric layer 51 may include a material having a lower dielectric constant than the interlayer insulating layer 50. In an example, the interlayer insulating layer 50 may include TEOS, and the first dielectric layer 51 may include carbon doped silicon oxide (carbon doped silicon dioxide (SiO₂)) or fluorine doped silicon oxide (fluorine doped SiO₂).

Subsequently, second openings OP2 may be formed in the first dielectric layer 51. In an example, the second openings OP2 may be formed by etching the first dielectric layer 51 using a mask pattern as an etching barrier. The second openings OP2 may be arranged along the first direction I, and may be separated from each other. Each of the second openings OP2 may have a cross section with a tapered shape of which a lower portion is narrower than an upper portion.

Third openings OP3 may be formed in the first dielectric layer 51. The third openings OP3 may be arranged along the first direction I, and may be separated from each other. The third openings OP3 may be staggered with the second openings OP2. Each of the third openings OP3 may have a cross section with a tapered shape of which a lower portion is narrower than an upper portion.

The second openings OP2 and the third openings OP3 may be simultaneously formed. In an example, the second openings OP2 and the third openings OP3 may be formed by etching the first dielectric layer 51 using a mask pattern as an etching barrier.

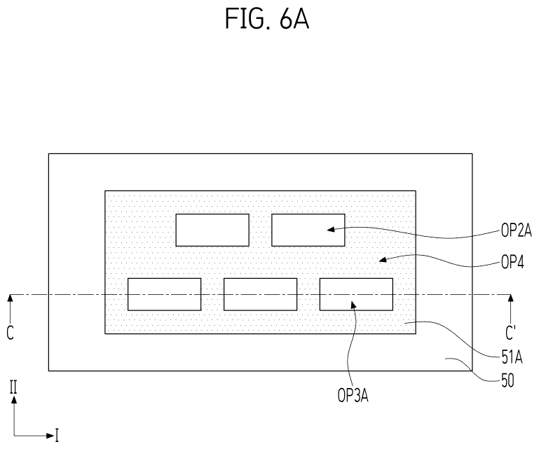

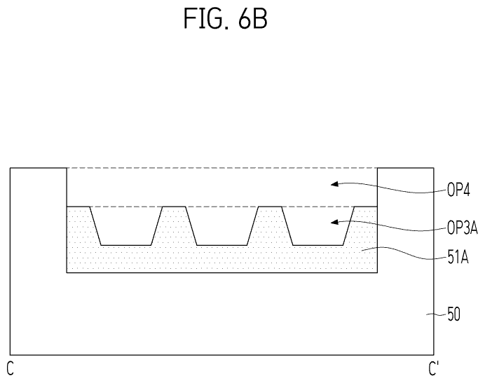

Referring to FIG. 6A and cross-sectional view FIG. 6B, taken along the line C-C′ of FIG. 6A, a fourth opening OP4 connecting the second openings OP2 and the third openings OP3 to each other may be formed in the interlayer insulating layer 50. In an example, the fourth opening OP4 may be formed by etching the first dielectric layer 51 using a mask pattern as an etching barrier. Inner walls of the interlayer insulating layer 50 may be exposed through the fourth opening OP4. An upper surface of the etched first dielectric layer 51A may be located lower than an upper surface of the interlayer insulating layer 50. As the first dielectric layer 51A is etched, depths of the second openings OP2 and the third openings OP3 may be reduced, and the second openings OP2A and the third openings OP3A having the reduced depths may be connected to the fourth opening OP4.

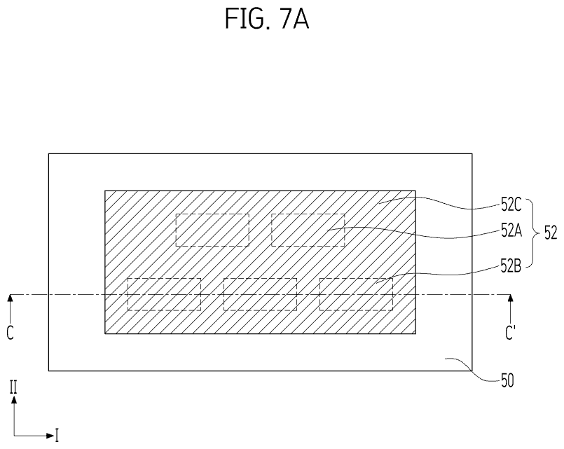

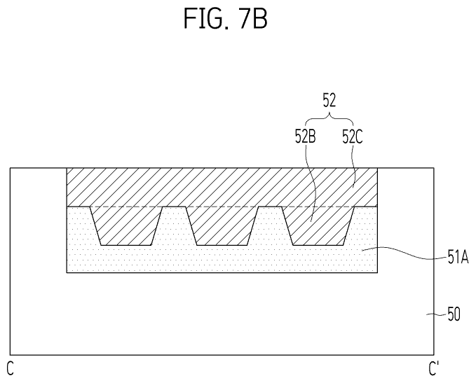

Referring to FIG. 7A and cross-sectional view FIG. 7B, taken along the line C-C′ of FIG. 7A, a conductive layer 52 may be formed in the second openings OP2A, the third openings OP3A, and the fourth opening OP4. The conductive layer 52 may include first conductive patterns 52A located in the second openings OP2A, third conductive patterns 52B located in the third openings OP3A, and a bulk conductive pattern 52C located in the fourth opening OP4. Each of the first and third conductive patterns 52A and 52B may have a reverse (or inverted) trapezoidal shape. The conductive layer 52 may include metal such as tungsten.

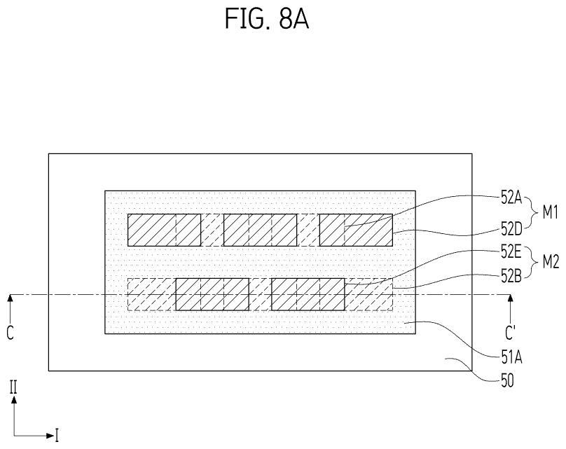

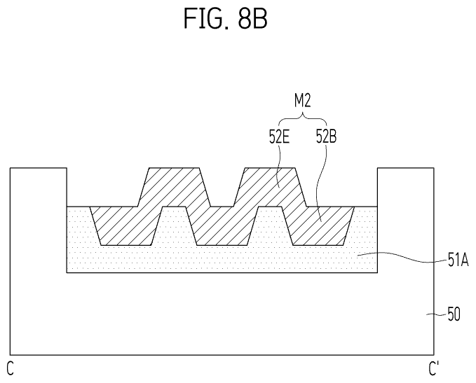

Referring to FIG. 8A and cross-sectional view FIG. 8B, taken along the line C-C′ of FIG. 8A, second conductive patterns 52D may be formed by etching the bulk conductive pattern 52C. In an example, the second conductive patterns 52D arranged in the first direction I may be formed by etching the bulk conductive pattern 52C using a mask pattern as an etching barrier. The second conductive patterns 52D may connect the first conductive patterns 52A to each other. Each of the second conductive patterns 52D may have a trapezoidal shape. Through this, a first wiring line M1 including the first conductive patterns 52A and the second conductive patterns 52D may be formed.

Fourth conductive patterns 52E may be formed by etching the bulk conductive pattern 52C. The fourth conductive patterns 52E may be arranged in the first direction I, and may connect the third conductive patterns 52B to each other. The fourth conductive patterns 52E may be staggered with the second conductive patterns 52D. Each of the fourth conductive patterns 52E may have a trapezoidal shape. Through this, a second wiring line M2 including the third conductive patterns 52B and the fourth conductive patterns 52E may be formed.

The first wiring line M1 and the second wiring line M2 may be simultaneously formed. The second conductive patterns 52D and the fourth conductive patterns 52E may be formed by etching the bulk conductive pattern 52C using the mask pattern as the etching barrier. The first wiring line M1 and the second wiring line M2 may extend in parallel along the first direction I.

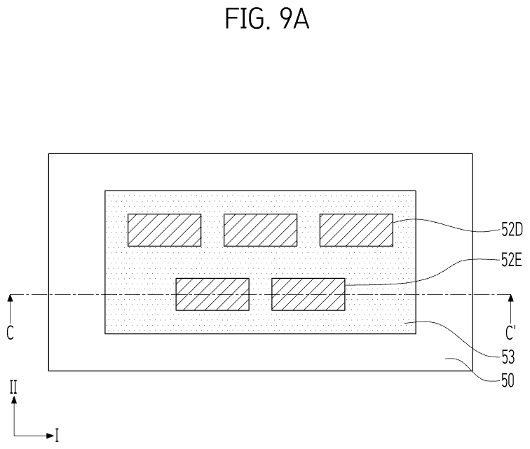

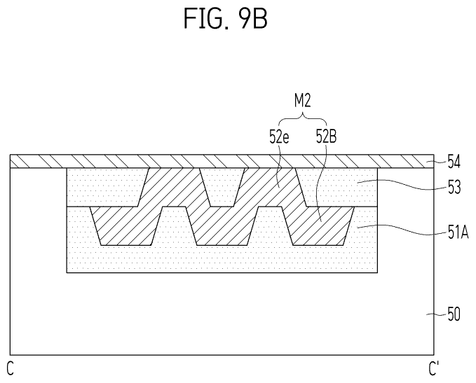

Referring to FIG. 9A and cross-sectional view FIG. 9B, taken along the line C-C′ of FIG. 9A, a second dielectric layer 53 may be formed on the first wiring line M1 and the second wiring line M2. The second dielectric layer 53 may include a material having a lower dielectric constant than the interlayer insulating layer 50. In an example, the interlayer insulating layer 50 may include TEOS, and the second dielectric layer 53 may include carbon doped silicon oxide (carbon doped SiO₂) or fluorine doped silicon oxide (fluorine doped SiO₂).

Subsequently, a capping layer 54 may be formed on the second dielectric layer 53. The capping layer 54 may be used to protect the first and second wiring lines M1 and M2. The capping layer 54 may include a material having a higher dielectric constant than the interlayer insulating layer 50. In an example, the capping layer 54 may include nitride.

According to the method described above, the first and second wiring lines M1 and M2 extending in parallel along the first direction I and staggered in the vertical direction may be formed. The first and second wiring lines M1 and M2 may be formed in the first and second dielectric layers 51A and 53 each including a low-k material. Accordingly, capacitance between the first and second wiring lines M1 and M2 may be reduced, and a bridge may be reduced. In addition, because only the second conductive patterns 52D in the first wiring line M1 are in contact with the capping layer 54 and only the fourth conductive patterns 52E in the second wiring line M2 are in contact with the capping layer 54, a path through which the bridge occurs may be reduced.

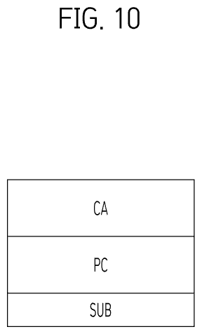

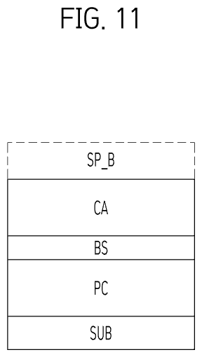

The structure and the manufacturing method according to the above-described embodiments may be applied to semiconductor devices of various structures. FIGS. 10 and 11 illustrate a schematic configuration of a semiconductor device to which the above-described embodiments are applicable.

FIG. 10 is a configuration diagram of a semiconductor device according to an embodiment of the present disclosure.

Referring to FIG. 10, the semiconductor device may include a substrate SUB, a peripheral circuit PC, and a memory cell array CA. Here, the peripheral circuit PC and the memory cell array CA may be formed on the same substrate.

The substrate SUB may be made of or include a semiconductor material. In an embodiment, the semiconductor material may include at least one of a group IV semiconductor, a group III-V compound semiconductor, and a group II-VI compound semiconductor. Here, the group IV semiconductor may include single crystal silicon Si, polycrystalline silicon, germanium Ge, or silicon germanium SiGe. The group III-V compound semiconductor may include GaAs, GaN, GaP, GaAsP, GaInAsP, AlAs, AlGa, InP, InSb, or InGaAs. The group II-VI compound semiconductor may include ZnS, ZnO, or CdS.

The substrate SUB may include a dielectric layer. The substrate SUB may be a silicon-on-insulator (SOI) substrate, a germanium-on-insulator (GeOI) substrate, or a glass substrate. The substrate SUB may include an organic material. In an embodiment, the substrate SUB may include graphene.

The substrate SUB may be a bulk wafer or an epitaxial layer grown in a selective epitaxial growth (SEG) method. The substrate SUB may be a layer formed in a metal induced lateral crystallization (MILC) method and may partially include metal. The substrate SUB may have a single crystalline, polycrystalline, or amorphous state. The substrate SUB may include an impurity of group II, group III, group IV, group V, or group VI. In an embodiment, the substrate SUB may include an n-well region doped with an n-type impurity and/or a p-well region doped with a p-type impurity.

The peripheral circuit PC may be disposed between the substrate SUB and the memory cell array CA. The peripheral circuit PC may include a row decoder, a column decoder, a page buffer, a logic circuit, a control circuit, a sense amplifier, an input/output circuit, and the like. In an embodiment, the peripheral circuit PC may include an NMOS transistor, a PMOS transistor, a resistor, a capacitor, and the like. The peripheral circuit PC may further include an interconnection structure. The interconnection structure may be used as a path for transferring an operation voltage, and may include a contact plug, a line, and the like.

The memory cell array CA may include memory cells. In an embodiment, the memory cell array CA may include memory strings connected between a source line and a bit line, and each memory string may include stacked memory cells. In an embodiment, the memory cell array CA may include memory cells connected between a word line and a bit line. The memory cell array CA may further include an interconnection structure.

FIG. 11 is a configuration diagram of a semiconductor device according to an embodiment of the present disclosure.

Referring to FIG. 11, the semiconductor device may include a substrate SUB, a peripheral circuit PC, a bonding structure BS, and a memory cell array CA. Here, the peripheral circuit PC and the memory cell array CA may be respectively formed on separate substrates and then bonded. The semiconductor device may further include a support base SP_B.

The substrate SUB may be used as a support in a process of forming the peripheral circuit PC. The support base SP_B may be used as a support in a process of forming the memory cell array CA. In an embodiment, after respectively manufacturing a first wafer including the memory cell array CA and a second wafer including the peripheral circuit PC, the first wafer and the second wafer may be electrically connected by the bonding structure BS. After bonding, at least a portion of the support base SP_B of the first wafer may be removed. The support base SP_B may be completely removed or may partially remain on the memory cell array CA.

The support base SP_B may be a semiconductor substrate, an insulating substrate, a silicon-on-insulator (SOI) substrate, a germanium-on-insulator (GeOI) substrate, or the like. The support base SP_B may be a bulk wafer, an epitaxial layer grown in a selective epitaxial growth (SEG) method, or a layer formed in a metal induced lateral crystallization (MILC) method. The support base SP_B may have a single crystalline, polycrystalline, or amorphous state. The support base SP_B may include an impurity of group II, group III, group IV, group V, or group VI.

The bonding structure BS may be for connecting the memory cell array CA and the peripheral circuit PC. In an embodiment, the memory cell array CA and the peripheral circuit PC may be bonded in a wafer-on-wafer bonding method, a chip-on-wafer bonding method, a chip-on-chip bonding method, or the like. The bonding structure BS may include a bonding pad, a bonding layer, a bonding interface, and the like. The bonding pad may include a metal such as copper and aluminum, and/or an alloy. The bonding interface may include a non-metal-non-metal interface, a metal-metal interface, or the like. The memory cell array CA and the peripheral circuit PC may be electrically connected by the bonding structure BS.

For reference, an interconnection structure included in the memory cell array CA and/or the peripheral circuit PC may be directly connected without a bonding pad. In an embodiment, a bonding layer included in the memory cell array CA and a bonding layer included in the peripheral circuit PC may be bonded to form a bonding interface, and the interconnection structure included in the memory cell array CA and the interconnection structure included in the peripheral circuit PC may be directly connected. Through this, contact plugs, lines, and the like formed on different wafers may be electrically connected without a separate bonding pad.

Other configurations may be equal or similar to those described above with reference to FIG. 10.

Meanwhile, the semiconductor device may have a structure in which the embodiments described above with reference to FIGS. 10 and 11 are combined or may have a partially modified structure. In the embodiment described with reference to FIGS. 10 and 11, positions of the memory cell array CA and the peripheral circuit PC may be changed. At least one memory cell array CA and/or at least one peripheral circuit PC may be additionally bonded to the embodiment described with reference to FIGS. 10 and 11. In an embodiment, a portion of the peripheral circuitry PC may be disposed in the memory cell array CA.

Although embodiments according to the technical idea of the present disclosure have been described above with reference to the accompanying drawings, this is only for explaining the embodiments according to the concept of the present disclosure, and the present disclosure is not limited to the above embodiments. Various types of substitutions, modifications, changes, and combinations for the embodiments may be made by those skilled in the art, to which the present disclosure pertains, without departing from the technical idea of the present disclosure defined in the following claims, and it should be construed that these substitutions, modifications, changes, and combinations belong to the scope of the present disclosure.

What is claimed is:

1. A semiconductor device comprising:
a first dielectric layer;
a second dielectric layer located over the first dielectric layer; and
a first wiring line including first conductive patterns located in the first dielectric layer, each of the first conductive patterns having an inverted trapezoidal shape, and second conductive patterns located in the second dielectric layer, each of the second conductive patterns having a trapezoidal shape, wherein the first conductive patterns and the second conductive patterns are alternately connected to each other.

2. The semiconductor device of claim 1, wherein long sides of parallel opposite sides of the first conductive patterns and long sides of parallel opposite sides of the second conductive patterns are in contact with each other.

3. The semiconductor device of claim 1, wherein the first wiring line is connected to a high-voltage transistor.

4. The semiconductor device of claim 1, further comprising a second wiring line including third conductive patterns located in the first dielectric layer, each of the third conductive patterns having an inverted trapezoidal shape, and fourth conductive patterns located in the second dielectric layer, each of the fourth conductive patterns having a trapezoidal shape, wherein the third conductive patterns and the fourth conductive patterns are alternately connected to each other.

5. The semiconductor device of claim 4, wherein the first wiring line and the second wiring line extend in parallel along a first direction, and are adjacent to each other in a second direction intersecting the first direction.

6. The semiconductor device of claim 5, wherein the first conductive patterns and the fourth conductive patterns are adjacent to each other in the second direction, and
the second conductive patterns and the third conductive patterns are adjacent to each other in the second direction.

7. The semiconductor device of claim 4, wherein during a program operation, a program voltage is transmitted through the first wiring line, and a pass voltage is transmitted through the second wiring line.

8. The semiconductor device of claim 4, wherein a program voltage is transmitted through the first wiring line, and a ground voltage is transmitted through the second wiring line.

9. The semiconductor device of claim 4, wherein an erase voltage is transmitted through the first wiring line, and
a ground voltage is transmitted through the second wiring line.

10. The semiconductor device of claim 4, wherein an erase voltage is transmitted through the first wiring line, and
a page buffer control signal is transmitted through the second wiring line.

11. The semiconductor device of claim 1, further comprising a capping layer located over the second dielectric layer and including a material having a higher dielectric constant than the first dielectric layer and the second dielectric layer.

12. The semiconductor device of claim 1, further comprising:
a peripheral circuit;
a first interconnection structure including the first wiring line electrically connected to the peripheral circuit;
a memory cell array including a gate structure and a channel structure extending through the gate structure;
a second interconnection structure electrically connected to the memory cell array; and
a bonding structure electrically connecting the peripheral circuit and the memory cell array to each other.

13. The semiconductor device of claim 1, further comprising:
a peripheral circuit;
a first interconnection structure electrically connected to the peripheral circuit;
a memory cell array including a gate structure and a channel structure extending through the gate structure;
a second interconnection structure including the first wiring line electrically connected to the memory cell array; and
a bonding structure electrically connecting the peripheral circuit and the memory cell array to each other.

14. A semiconductor device comprising:
a first dielectric layer;
a second dielectric layer located over the first dielectric layer;
a first wiring line including first conductive patterns located in the first dielectric layer and second conductive patterns located in the second dielectric layer, the first conductive patterns and the second conductive patterns being alternately connected to each other; and
a second wiring line including third conductive patterns located in the first dielectric layer and fourth conductive patterns located in the second dielectric layer, the third conductive patterns and the fourth conductive patterns being alternately connected to each other,
wherein the first wiring line and the second wiring line extend in parallel along a first direction.

15. The semiconductor device of claim 14, wherein the first conductive patterns and the fourth conductive patterns are adjacent to each other in a second direction intersecting the first direction, and
the second conductive patterns and the third conductive patterns are adjacent to each other in the second direction.

16. The semiconductor device of claim 14, wherein a high-voltage signal is transmitted through the first wiring line, and a low-voltage signal is transmitted through the second wiring line.

17. The semiconductor device of claim 16, wherein the high-voltage signal includes a program voltage or an erase voltage.

18. The semiconductor device of claim 16, wherein the low-voltage signal includes a pass voltage, a ground voltage, or a control signal.
